(19) United States
(12) Patent Application Publication
(10) Pub. No.: US 2019/0267480 A1
(43) Pub. Date: Aug. 29, 2019

(54) ANTI-BARRIER-CONDUCTION (ABC) SPACERS FOR HIGH ELECTRON-MOBILITY TRANSISTORS (HEMTS)

(71) Applicant: DUET MICROELECTRONICS INC., Raritan, NJ (US)

(72) Inventors: Ashok T. Ramu, Raritan, NJ (US); Keun-Yong Ban, Raritan, NJ (US)

(73) Assignee: DUET MICROELECTRONICS INC., Raritan, NJ (US)

(21) Appl. No.: 16/239,909

(22) Filed: Jan. 4, 2019

Related U.S. Application Data
(63) Continuation-in-part of application No. 15/918,003, filed on Mar. 12, 2018, now abandoned.
Application No. 15/918,003 is a continuation-in-part of application No. 15/905,295, filed on Feb. 26, 2018.

(51) Int. Cl. H01L 29/778; H01L 29/66

(52) U.S. Cl. CPC H01L 29/7783; H01L 29/66462

(57) ABSTRACT

A field effect transistor (FET) includes a substrate, a back barrier disposed on the substrate, a channel disposed on the back barrier, a front barrier disposed on the channel, a source, and a drain, such that at least one of the front barrier and the back barrier includes an anti-barrier-conduction (ABC) spacer which reduces parasitic conduction on a path from the source to the drain through at least one of the front barrier and the back barrier, reduces ON-state leakage from the channel to gate or substrate of the FET via resonant tunneling, and reduces OFF-state leakage by presenting tall barriers to electrons as well as electron-holes. This results in a highly linear, low gate leakage, low parasitic conduction, and low noise operation of FET.

### CROSS-REFERENCE TO RELATED APPLICATIONS

This application claims priority to U.S. application Ser. No. 15/905,295, filed on Feb. 26, 2018, and U.S. application Ser. No. 15/918,003, filed on Mar. 12, 2018, each of which is incorporated by reference in its entirety.

### FIELD

The present disclosure relates to high electron-mobility transistors (HEMTs) and in particular to anti-barrier-conduction (ABC) spacers for HEMTs.

### BACKGROUND

Electrons are described by quantum mechanics for length scales on the order of the thicknesses of the channel and the barrier of HEMTs known in the art. A typical example of an HEMT 10 in the prior art is shown in FIG. 1, which has a source 12, a gate 14, a drain 16, a conducting cap 18, a front barrier 20, a pulse-doping layer 22 incorporated within the front barrier 20, a channel 24, and a back barrier 26 formed on a substrate 28, with an optional pulse-doping layer 30 incorporated within the back barrier 26. The source 12, the gate 14, and the drain 16 are composed of metal layers. In an example embodiment, the front barrier 20 is an AlGaAs alloy composed of 28% Al, the channel 24 is an InGaAs alloy composed of 20% In, the back barrier 26 is an AlGaAs alloy composed of 28% Al, and the substrate 28 is composed of GaAs. It is understood that an infinity of combinations of elements and alloy concentrations are possible for the HEMT 10.

As shown in FIG. 2, an example of a conduction band profile is taken vertically through the center of the HEMT 10 of FIG. 1, excluding the gate 14. As can be seen in FIG. 2, the thicknesses of the front barrier 20, the channel 24, and the back barrier 26 are on the order of a fraction of a micron, requiring the behavior of the electrons in the HEMT 10 to be described by quantum mechanics.

Based on quantum mechanics and statistical mechanics, electrons have wave-like behavior at such sub-micron scales, which can be described by a wavefunction representing their probability of being located at a certain point. Electrons in a potential “well” can take one of a set of discrete or quantized energy “levels”, each corresponding to a specific wavefunction. The wavefunctions corresponding to discrete energies are called “bound states”, and such bound states and their energies are found by solving the Schrodinger wave equation. Solutions to the Schrodinger wave equation show that the deeper the potential well, the higher in energy are its bound states.

The charge density p at a point z is proportional to the sum of the squares of the absolute value of the wavefunctions, weighted by a factor that depends on how far the bound state energy is from a reference level called the “Fermi level”. The charge density p at any point z along the quantized direction may be written as:

$$ρ ( z ) = \frac{2 {qk}_{B} {Tm}^{*}}{π {h}^{2}} {\sum }_{i = 1}^{∞} {⌈ {ψ}_{i} ( z ) ⌉}^{2} log ⌈ 1 + {e}^{( {E}_{F} - {E}_{i} ) / {k}_{B} T} ⌉$$

in which k_{B} is the Boltzmann constant equaling 1.38×10⁻²³ Joule/Kelvin, q is the charge of an electron, T is the temperature, m* is the “effective” mass of an electron in the potential well, h is Planck's constant equaling 6.626×10⁻³⁴ Joule-second, Ψᵢ is the bound state indexed by i, Eᵢ is the corresponding bound state energy, and E_{F} is the energy at the Fermi level. The summation is to be executed over all states, bound or otherwise.

As described below, the energy E_{F} at the Fermi level will be taken to be 0 electron-volts in energy. Based on the above equation, the lower the bound-state in energy compared to the energy E_{F} of the Fermi level, the bigger the assigned weight to that state, and the larger its contribution to the charge density p.

As shown in FIG. 2, the conduction-band profile of a HEMT channel surrounded by barrier materials is a manifestation of a potential “well”, and thus the definitions and the equation above apply with modifications well known to someone skilled in the art.

Bound states may be formed in the channel 24 and/or the barriers 20, 26 of the HEMT 10. Bound states in the barriers 20, 26 are formed due to the shape of the conduction band profile caused by the introduction of intentional impurities, which are called electron donors in the exemplary HEMT 10 in FIG. 1. The bound states of the channel 24 and the barriers 20, 26 are not isolated but instead interact with each other. The strength of this interaction depends on how close the bound states are in energy. If the energies of the bound states of the channel 24 and either of the barriers 20, 26 coincide to within a few ten millivolts, the overall wavefunction will have a substantial presence in both areas, in which case the bound states of the channel 24 and the barriers 20, 26 are said to be “in resonance”.

HEMTs in the prior art may include one or more delta (or pulse) doping layers in one or more barriers. Delta doping layers with large sheet concentrations between 1×10¹² cm² and 4×10¹² cm² may need to be placed in one or more barriers of the HEMTs in order to meet device performance specifications such as transconductance, current handling capability, and linearity.

FIG. 3 shows a desired path 32 for electron conduction from a source 12 to a drain 16 through the high-mobility HEMT channel 24 in the prior art as well as two parasitic paths 34, 36 through the low-mobility barriers 20, 26 which may be intentionally doped and/or impure barriers. FIG. 4 illustrates an HEMT structure in the prior art having a double-delta doped structure for linearity improvement, but which has the thicknesses of its layers in the sub-micron or nanometer range, such that quantum mechanical effects of the wave-like nature of the electrons increase the effects of such parasitic paths 34, 36 shown in FIG. 3.

FIGS. 5A-5B show a simulated HEMT design in the prior art, with FIG. 5A plotting a conduction band edge versus the vertical distance in the HEMT 10, while FIG. 5B plots the electron density versus the vertical distance in the HEMT 10. According to FIGS. 5A-5B, a barrier 20, 26 has a high charge density, and carries a third to half of the electron concentration compared to the peak of the electron concentration in the channel 24 over similar thicknesses. Such high electron concentrations in a barrier 20, 26 corresponds to a large contribution to through-barrier parasitic conduction in the paths 34, 36 as shown in FIG. 3.

HEMTs in the prior art also display what is known as the “kink effect”, in which a current in the drain rises uncontrollably above a saturated value beyond a certain drain voltage. The kink effect is believed to be caused by hole accumulation in the channel near the source end. Therefore, it is desirable to suppress hole transmission across the barriers 20, 26 in an HEMT 10 as in FIG. 1.

### SUMMARY

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

The present invention enables the fabrication of HEMTs with highly doped HEMT barriers and with a reduced electron charge density in the barriers to reduce parasitic conduction through the nominally insulating barriers of the HEMT, even in highly doped barriers. Such reductions in electron charge density are caused by having the bound-state energy Eᵢ be as far above the Fermi energy level E_{F} as possible.

The present invention keeps electrons confined to the channel when the device is in the ON-state by reducing the resonant-tunneling mechanism which causes the ON-state leakage of channel electrons through the barriers and into the gate and/or the substrate.

By keeping the electrons confined to the channel, the HEMT of the present invention has an increased speed of operation by reducing scattering by donor impurities in the barrier, thus increasing the mobility.

By reducing the tunneling as well as thermionic emission of channel electrons as well as electron-holes through the front barrier into the gate, the present invention reduces OFF-state (or sub-threshold) gate leakage, and thus also reduces device noise.

The present invention also reduces the kink-effect caused by electron-holes accumulating near the source end of the channel due to tunneling or thermionic emissions across the front and/or back barriers, and increasing the drain current, sometimes abruptly through an avalanche breakdown process.

The present invention also increases the effective Schottky barrier height, which enables enhancement-mode operation of the HEMT, as described in U.S. application Ser. No. 15/918,003, filed on Mar. 12, 2018, which is incorporated by reference in its entirety.

The present invention includes placing one or more thin layers of wide-bandgap (WBG) materials, such as AlAs, on either side of the potential well, with such thin WBG layers being anti-barrier-conduction (ABC) spacers.

In one embodiment, the present invention is a field effect transistor (FET) including: a substrate, a back barrier disposed on the substrate, a channel disposed on the back barrier, and a front barrier disposed on the channel, wherein at least one of the front barrier and the back barrier includes an anti-barrier-conduction (ABC) spacer. The ABC spacer is grown by a fabrication method selected from molecular beam epitaxy (MBE), metal-organic chemical vapor deposition (MOCVD), atomic layer deposition (ALD), thermal evaporation, and sputtering. The ABC spacer is grown by a fabrication method selected from a lattice-matched growth, pseudo-morphic growth and a metamorphic growth. The ABC spacer may be disposed adjacent to the channel. The ABC spacer causes a conduction-band offset in the range of +0.1 eV to +10 eV relative to and above at least one of the front barrier and the back barrier. The ABC spacer is composed of a wide-bandgap (WBG) material. The FET further includes a source, a drain, and a gate, and the ABC spacer may be disposed between the gate and the front barrier.

The ABC spacer reduces parasitic conduction on a path from the source to the drain through at least one of the front barrier and the back barrier. A pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb. The ABC spacer reduces ON-state leakage into the gate caused by resonant tunneling from the channel, reduces thermionic emission of electrons over one at least of the front and back barriers, reduces thermionic emission of electron-holes over at least one of the front and back barriers, reduces tunneling of electrons through at least one of the front and back barriers, reduces tunneling of electron-holes through at least one of the front and back barriers, improves the OIP3 figure of merit for linearity, reduces gate leakage, reduces substrate leakage, and reduces gate noise.

In another embodiment, the present invention is a high-electron mobility transistor (HEMT) including: a substrate, a back barrier disposed on the substrate, a channel disposed on the back barrier, a front barrier disposed on the channel, a pulse-doping layer disposed in at least one of the front barrier and the back barrier, and at least one of the front barrier and the back barrier includes an anti-barrier-conduction (ABC) spacer. The ABC spacer is composed of a wide-bandgap (WBG). The HEMT further includes: a source and a drain, and the ABC spacer reduces parasitic conduction on a path from the source to the drain through at least one of the front barrier and the back barrier. In another embodiment, the present invention is a high-electron mobility transistor (HEMT) including: a substrate, a back barrier disposed on the substrate, a channel disposed on the back barrier, a front barrier disposed on the channel, a pulse-doping layer disposed in at least one of the front barrier and the back barrier, and at least one of the front barrier and the back barrier includes an anti-barrier-conduction (ABC) spacer. The channel is a compositionally graded alloy such that the composition of one of the alloy constituents is varied in a piecewise linear or piecewise quadratic manner versus distance in the growth direction. The grading imparts high linearity to the HEMT, as quantified by the OIP3 figure-of-merit. The ABC spacer is composed of a wide-bandgap (WBG) material. The HEMT further includes: a source and a drain, and the ABC spacer reduces parasitic conduction on a path from the source to the drain through at least one of the front barrier and the back barrier.

A pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb. The ABC spacer reduces ON-state leakage into the gate caused by resonant tunneling from the channel, reduces thermionic emission of electrons over one at least of the front and back barriers, reduces thermionic emission of electron-holes over at least one of the front and back barriers, reduces tunneling of electrons through at least one of the front and back barriers, reduces tunneling of electron-holes through at least one of the front and back barriers, improves the OIP3 figure of merit for linearity, reduces gate leakage, reduces substrate leakage, and reduces gate noise.

In a further embodiment, the present invention is a method including: disposing a back barrier on a substrate, disposing a channel on the back barrier, disposing a front barrier on the channel, and disposing an anti-barrier-conduction (ABC) spacer in relation to at least one of the front barrier and the back barrier. The ABC spacer may be disposed adjacent to the channel. Alternatively, the ABC spacer is disposed within at least one of the front barrier and the back barrier. A source and a drain may be disposed above the front barrier, and the ABC spacer reduces parasitic conduction on a path from the source to the drain through at least one of the front barrier and the back barrier. The ABC spacer is composed of a wide-bandgap (WBG) material.

A pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb. The ABC spacer reduces ON-state leakage into the gate caused by resonant tunneling from the channel, reduces thermionic emission of electrons over one at least of the front and back barriers, reduces thermionic emission of electron-holes over at least one of the front and back barriers, reduces tunneling of electrons through at least one of the front and back barriers, reduces tunneling of electron-holes through at least one of the front and back barriers, improves the OIP3 figure of merit for linearity, reduces gate leakage, reduces substrate leakage, and reduces gate noise.

Gate and substrate leakage can be measured using current-voltage measurements, or through terminal noise measurements, or other techniques known in the art. The electron concentration and mobility in the channel and barrier may be deduced from Hall Effect measurements, or other methods as known in the art. Gate noise measurement techniques for HEMTs are well known in the art. Bound state energies and wave-functions in various regions of the device may be determined by simulation using Schrodinger-Poisson solvers and other techniques well known in the art.

### BRIEF DESCRIPTION OF DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 illustrates an HEMT in the prior art;

FIG. 2 illustrates a conduction band profile of the HEMT of FIG. 1;

FIG. 3 illustrates useful and parasitic conduction paths in the HEMT of FIG. 1;

FIG. 4 illustrates a HEMT in the prior art with example compositions and thicknesses of its layers;

FIG. 5A is a plot of conduction band edges versus vertical distance in an HEMT in the prior art;

FIG. 5B is a plot of charge density versus vertical distance in an HEMT in the prior art;

FIG. 6 illustrates an HEMT of the present invention having wide-bandgap anti-barrier-conduction spacers;

FIG. 7A illustrates a conduction band profile of the HEMT of the present invention in FIG. 6;

FIG. 7B illustrates a conduction band profile of the HEMT in the prior art in FIG. 1;

FIGS. 8A-8C illustrate conduction band profiles and wavefunctions of the HEMT of FIG. 1 in the prior art;

FIGS. 8D-8F illustrate conduction band profiles and wavefunctions of the HEMT of FIG. 6 of the present invention;

FIGS. 9A-9C illustrate additional conduction band profiles and wavefunctions of the HEMT of FIG. 1 in the prior art;

FIGS. 9D-9F illustrate additional conduction band profiles and wavefunctions of the HEMT of FIG. 6 of the present invention; and

FIG. 10 illustrates electron-hole traversal of the barriers into the channel or the gate in the HEMT of FIG. 6.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION

Certain terminology is used in the following description for convenience only and is not limiting. The article “a” is intended to include one or more items, and where only one item is intended the term “one” or similar language is used. Additionally, to assist in the description of the present invention, words such as top, bottom, side, upper, lower, front, rear, inner, outer, right and left may be used to describe the accompanying figures. The terminology includes the words above specifically mentioned, derivatives thereof, and words of similar import.

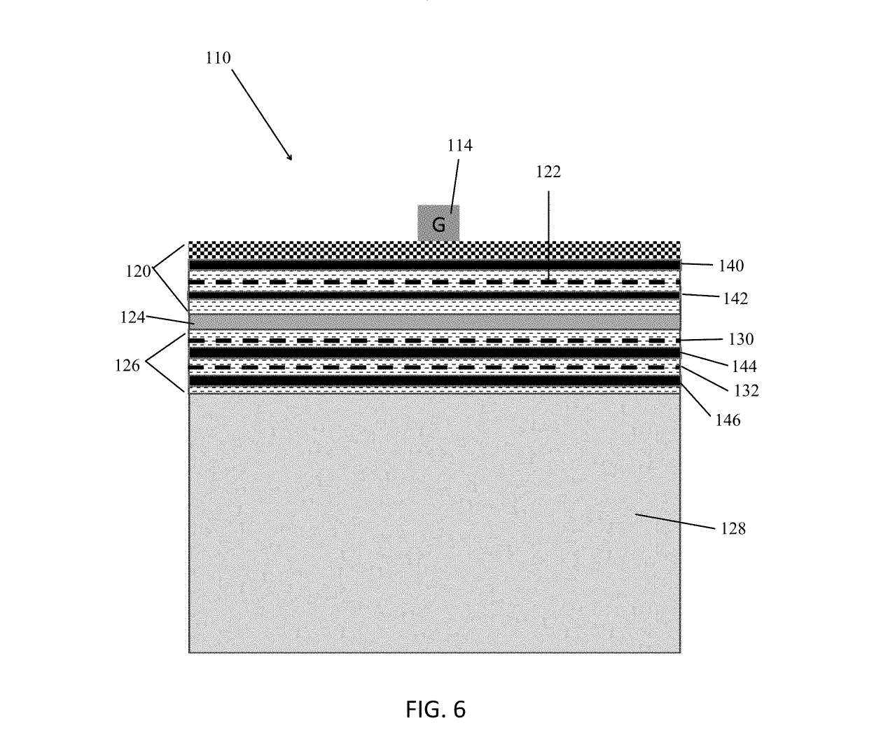

FIG. 6 illustrates an HEMT 110 of the present invention having wide-bandgap (WBG) anti-barrier-conduction (ABC) spacers 140, 142, 144, 146. The HEMT 110 includes a gate 114, a front barrier 120 having at least one pulse-doping layer 122, a channel 124, a back barrier 126 having at least one pulse-doping layer 130, 132, and a substrate 128. The ABC spacers 140, 142, 144, 146 are thin layers of wide-bandgap (WBG) materials, such as AlAs, GaP and other WBG materials known in the art placed on either side of the potential wells in one or both of the front and back barrier(s). In an example embodiment, the ABC spacers 140, 142 are placed within and/or adjacent to the front barrier 120, and the ABC spacers 144, 146 are placed within and/or adjacent to the back barrier 126.

The ABC spacers 140, 142, 144, 146 are formed from at least binary compounds or alloys which. may be grown by molecular beam epitaxy (MBE), by metal-organic chemical vapor deposition (MOCVD), by atomic layer deposition (ALD), by thermal evaporation, by sputtering, and/or by any known fabrication method. The ABC spacers 140, 142, 144, 146 may be grown in a lattice matched manner, or pseudo-morphically or metamorphically. The ABC spacers 140, 142, 144, 146 are formed in combination with another barrier material, or may be disposed either as a first barrier layer adjacent to the gate 114, or alternatively may be enclosed by other barrier material, or may be disposed adjacent to the channel 124. The ABC spacers 140, 142, 144, 146 are formed with a conduction-band offset in the range of, for example, +0.1 eV to +10 eV in electron energy relative to and above at least one other barrier material.

In an example embodiment, the HEMT 110 in FIG. 6 may be composed of the front barrier 120 having alternating layers of (Al)(In)(GaAs) and AlAs, with the AlAs being the ABC spacers 140, 142, and with the alternating layers disposed on a layer of AlGaAs. The front barrier 120 is disposed on a channel 124 composed of (In)GaAs, which is disposed on the back barrier 126, which in turn is disposed on the substrate 128. The back barrier 126 may be composed of alternating layers of AlGaAs and AlAs, with the AlAs being the ABC spacers 144, 146. Optional pulse doping layers 122, and 130, 132 are disposed in the front barrier 120 and the back barrier 126, respectively.

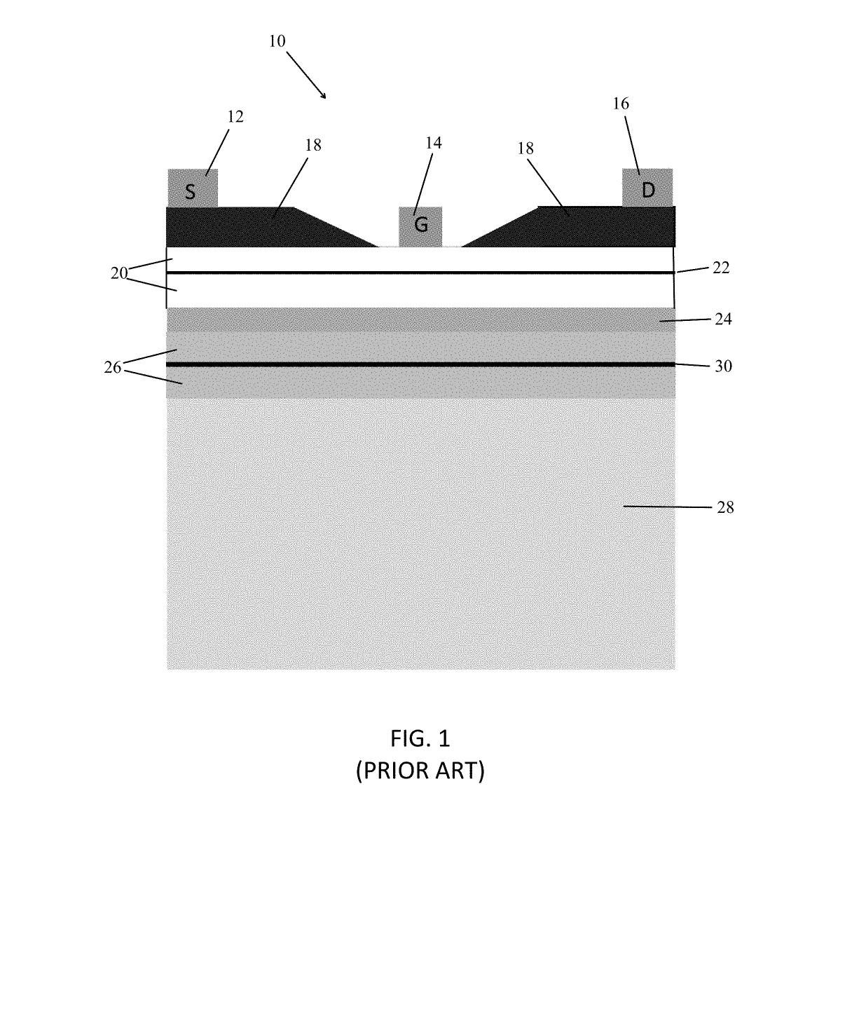

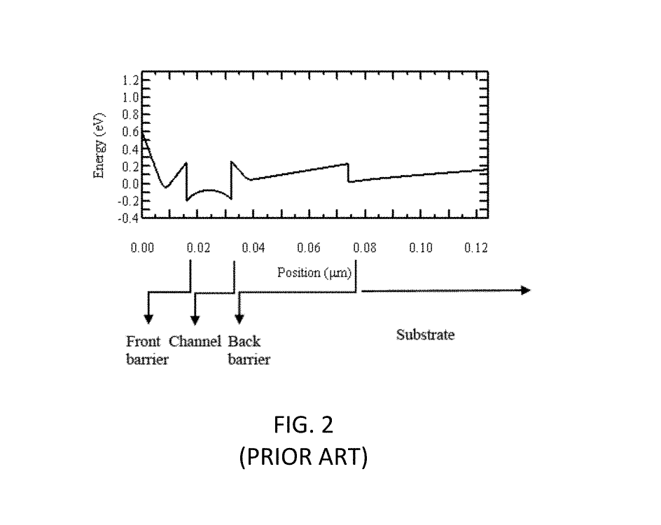

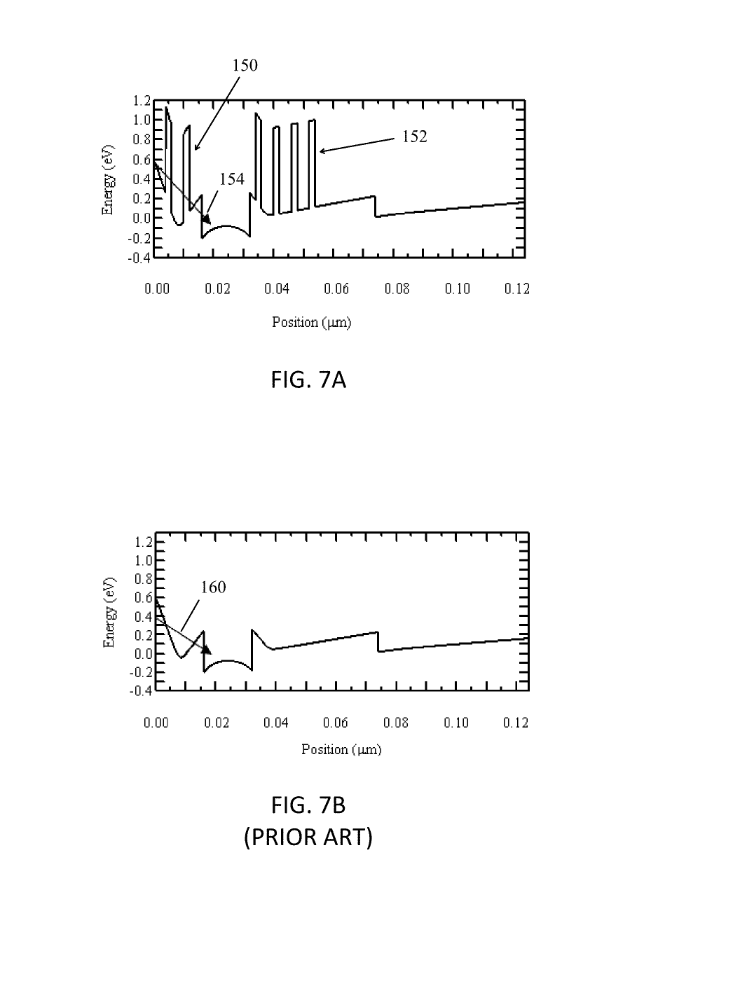

FIG. 7A illustrates a conduction band profile of the HEMT 110 taken vertically through the center of the HEMT 110 in FIG. 6, in which spikes 150, 152 are formed due to the presence of the ABC spacers 140, 142, 144, 146, which confer a reduction of tunneling current simply by virtue of offering taller barriers, even without the additional advantage of preventing resonant tunneling. Accordingly, the spikes 150, 152 prevent the flow 154 of electrons across the front barrier 120. The flow 154 represents the path of electron tunneling through, for example, the front barrier 120 of the HEMT 110 of the present invention. For comparison, FIG. 7B illustrates a conduction band profile of the HEMT 10 in the prior art in FIG. 1, with the profile in the prior art lacking the spikes as in the conduction band profile of the HEMT 110 of the present invention in FIG. 6. Accordingly, the flow 160 of electrons occurs across the front barrier in the profile in FIG. 7B, and so the tunneling of electrons in the HEMT 10 is unimpeded in the prior art, while the tunneling of electrons in the HEMT 110 in FIG. 7A is impeded, which prevents electron leakage effects.

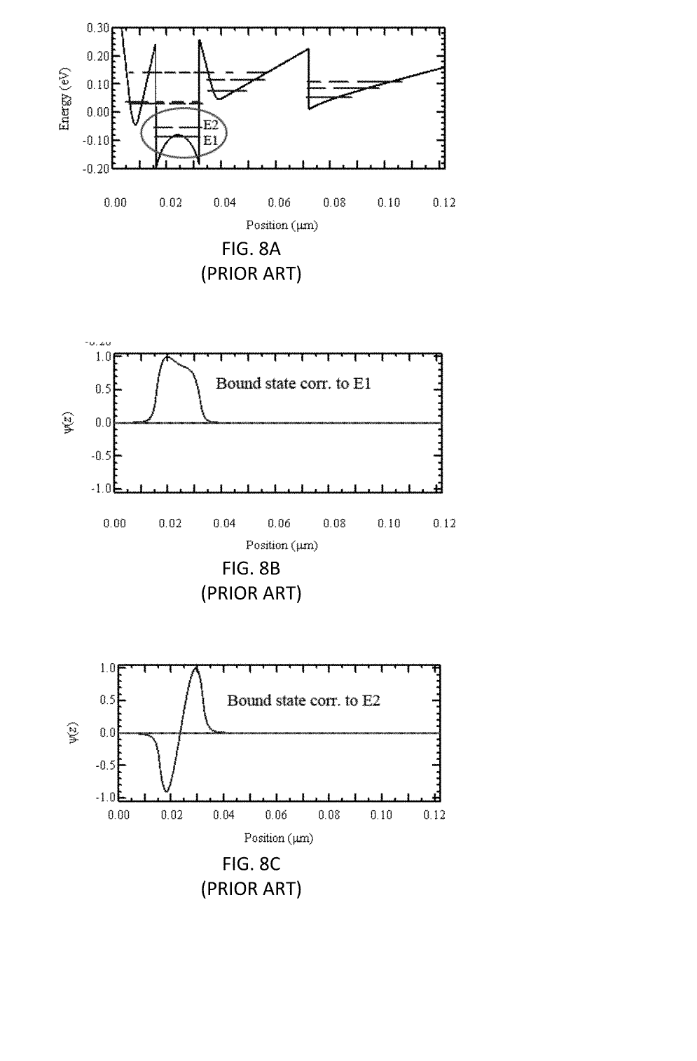

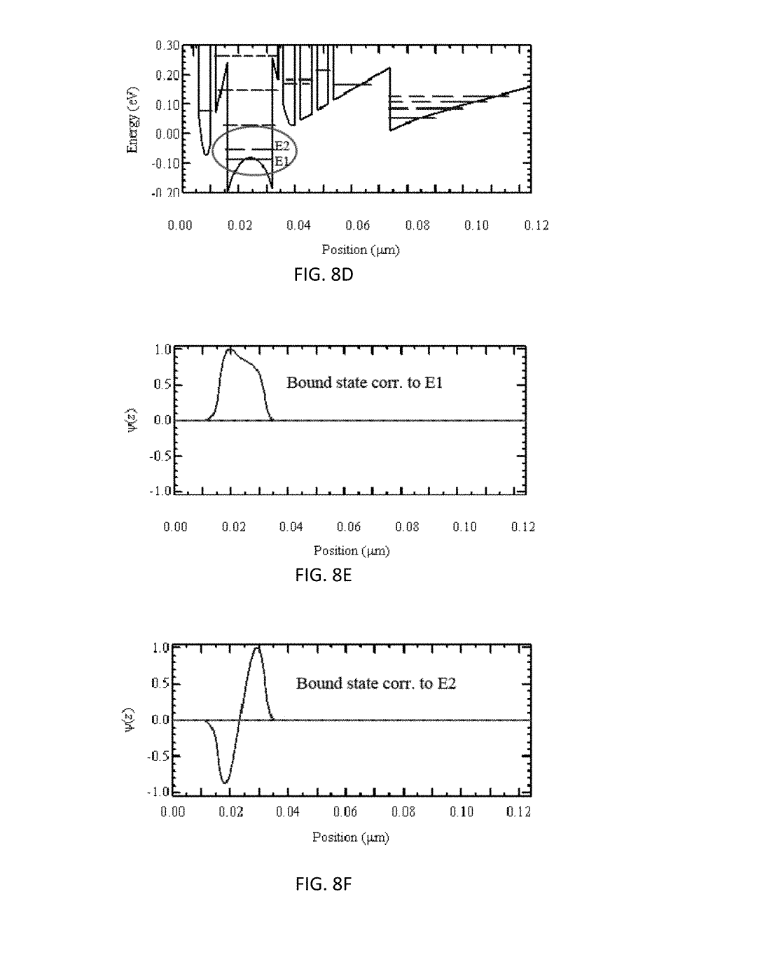

FIGS. 8A-8C illustrate conduction band profiles and wavefunctions of the HEMT 10 of FIG. 1 in the prior art, while FIGS. 8D-8F illustrate conduction band profiles and wavefunctions of the HEMT 110 of FIG. 6 according to the present invention. In particular, FIG. 8A illustrates energies E1 and E2 of the first two barrier-bound states in the prior art without ABC spacers in the HEMT 10. FIGS. 8B-8C illustrate wavefunctions corresponding to the lowest energy E1 and to the second lowest energy E2, respectively, for the bound states in the prior art. In contrast, FIG. 8D illustrates energies E1 and E2 of the first two bound states according to the present invention, with ABC spacers in the HEMT 110 in FIG. 6. FIGS. 8E-8F illustrate wavefunctions corresponding to the lowest energy E1 and to the second lowest energy E2, respectively, of the bound states according to the present invention in FIG. 6. It is clearly visible that the wavefunctions corresponding to E1, E2 bound states in the present invention are confined to the channel 124 of the HEMT 110 and are heavily occupied, by being below the Fermi energy level of 0 volts.

As shown in FIGS. 8D-8F compared to FIG. 8A-8C of the prior art, the ABC spacers 140, 142, 144, 146 in the barriers 120, 126, respectively, of the HEMT 110 in FIG. 6 do not materially affect the energies and wavefunctions of the lowest energy states. The increased depth of the wells in a barrier has very little effect on the channel bound-states that are lowest in energy, which is acceptable and desirable, because these lowest states tend to be well confined to the channel. Accordingly, there is a lack of effect of the ABC spacers 140, 142, 144, 146 on the lowest two bound states corresponding to the energy levels E1, E2 in the present invention.

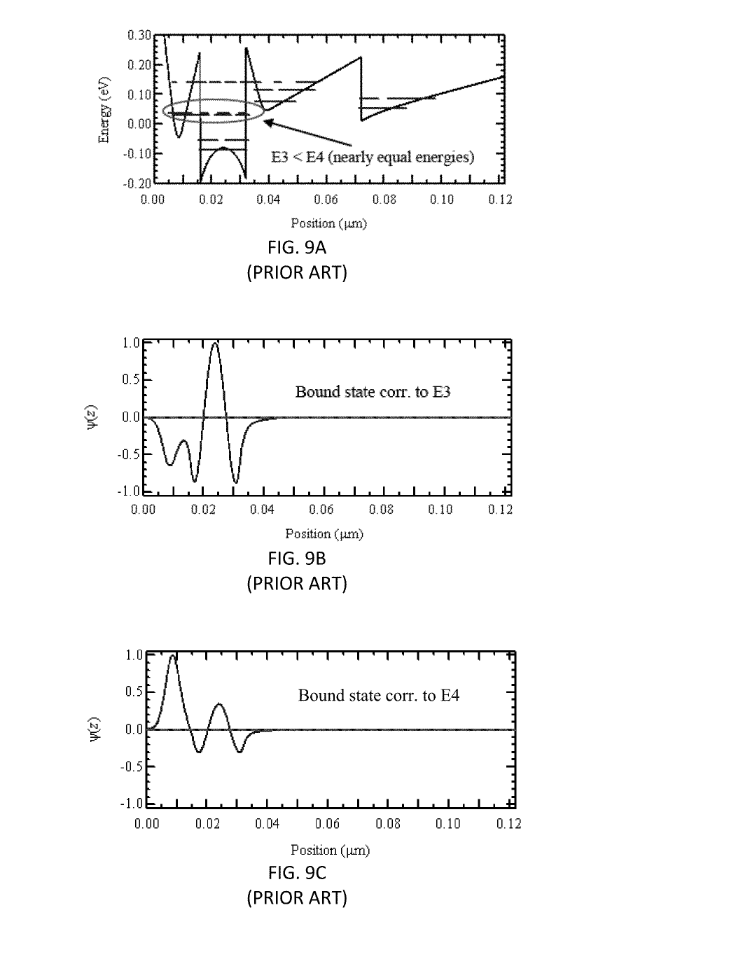

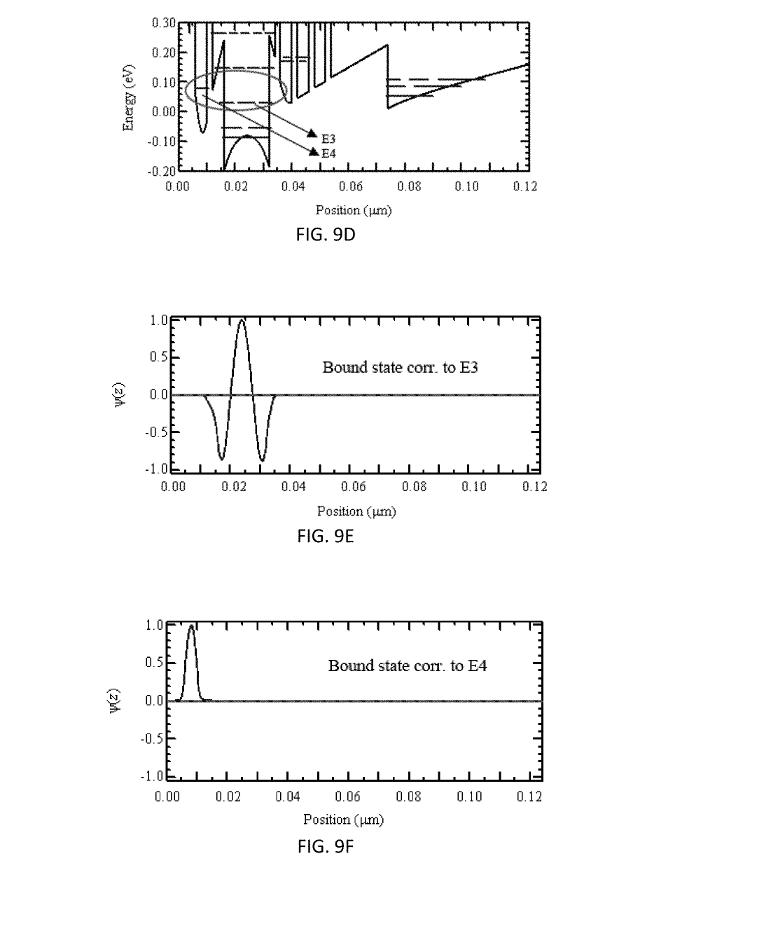

However, several advantages accrue to the speed, noise and other electrical characteristics of a HEMT due the modification of the third and fourth lowest bound states when ABC spacers are included, when compared to HEMTs in the prior art. FIGS. 9A-9C illustrate conduction band profiles and wavefunctions of the HEMT 10 of FIG. 1 in the prior art, while FIGS. 9D-9F illustrate conduction band profiles and wavefunctions of the HEMT 110 of FIG. 6 according to the present invention. In particular, FIG. 9A illustrates energies of several bound states including energies E3 and E4 in the prior art without ABC spacers in the HEMT 10, with E3<E4, although E3 and E4 are nearly equal energies. FIGS. 9B-9C illustrate wavefunctions corresponding to the third lowest energy E3 and to the fourth lowest energy E4, respectively, for the bound states in the prior art. In contrast, FIG. 9D illustrates energies of several bound states including energies E3 and E4 according to the present invention, with the ABC spacers 140, 142, 144, 146 in the HEMT 110 in FIG. 6. As can be seen in FIG. 9D, the energy levels E3 and E4 are no longer nearly equal energies in the present invention due to the presence of the ABC spacers 140, 142, 144, 146. FIGS. 9E-9F illustrate wavefunctions corresponding to the third lowest energy bound state corresponding to the energy level E3 and to the fourth lowest energy bound state corresponding to the energy level E4, respectively, according to the present invention in FIG. 6. As can be seen, the wavefunctions of the bound states corresponding to the energy levels of E3 and E4 in the present invention, shown in FIGS. 9E-9F, respectively, are significantly different from the wavefunctions of the bound states corresponding to the energy levels of E3 and E4 in the prior art, shown in FIGS. 9B-9C, respectively, due to the presence of the ABC spacers 140, 142, 144, 146 of the present invention.

With ABC spacers 140, 142, 144, 146 shown in FIG. 6, electrons are better confined to the channel 124 and overlap much less with scattering donors in the barriers 120, 126, thus improving their mobility. In addition, in the prior art, the third and fourth eigenstates without ABC spacers, labeled E3 and E4, respectively, as shown in FIG. 9A, are seen to be very close in energy. This enhances the resonant tunneling mechanism of electron leakage from the channel through the front barrier into the gate metal or through the back barrier into the substrate in the prior art, and gate leakage contributes to device noise in devices of prior art. On the contrary, in the present invention, the ABC spacers 140, 142, 144, 146 in FIG. 6 push the barrier bound states higher in energy, as shown in FIG. 9D, destroying this resonance and the associated leakage mechanism, as so the HEMT 110 of the present invention has reduced or no noise.

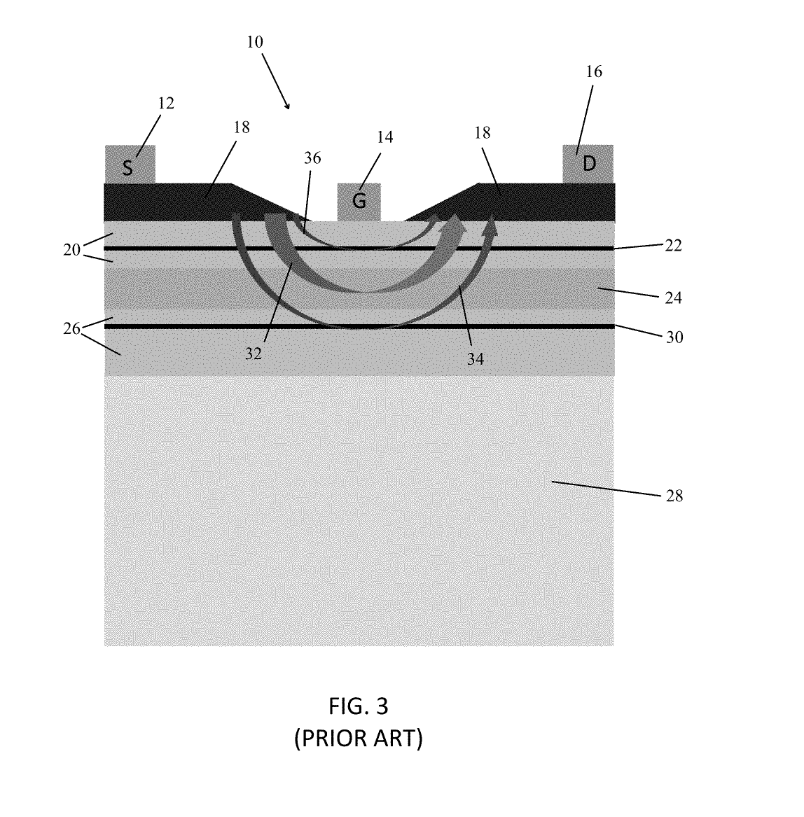

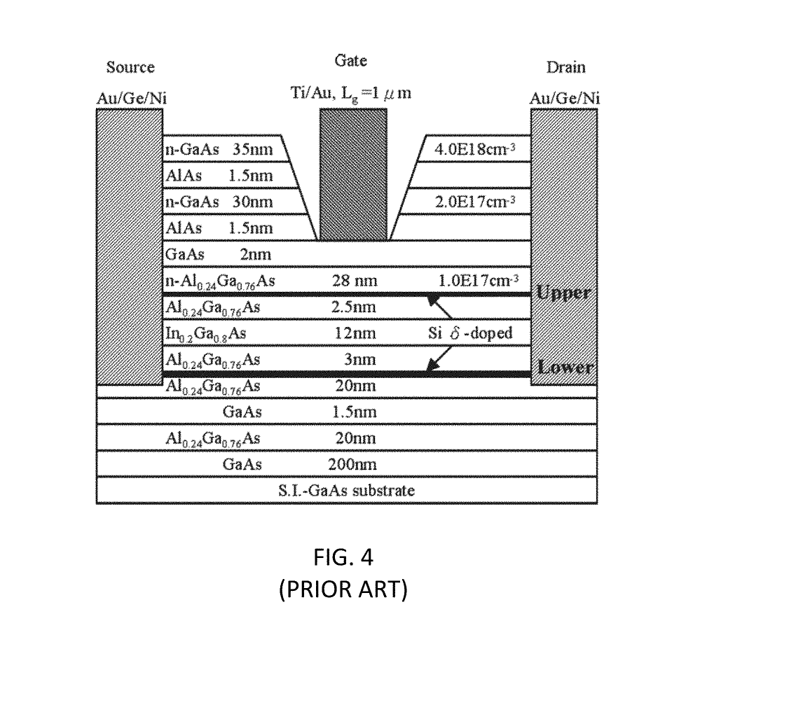

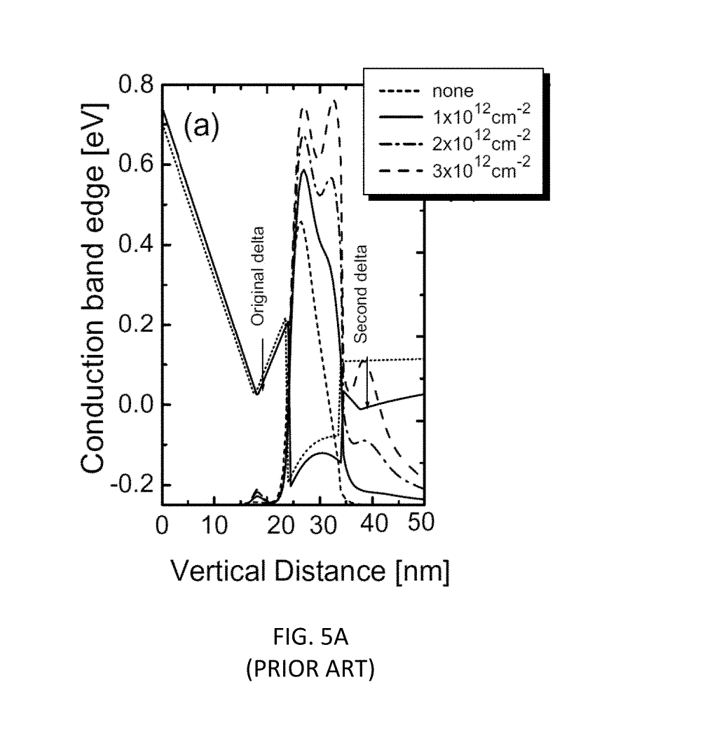

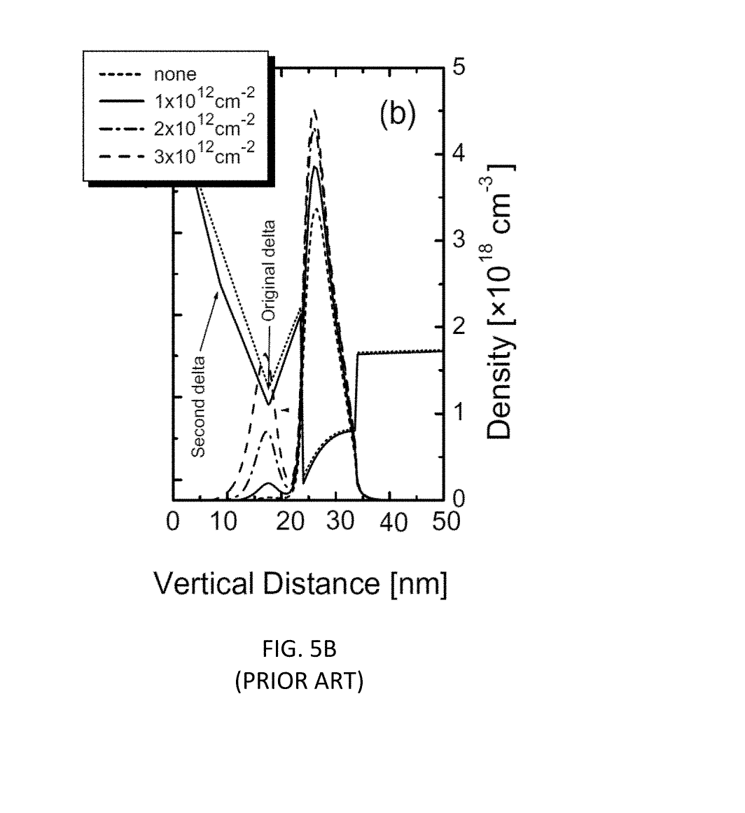

In addition, the ABC spacers 140, 142, 144, 146 in FIG. 6 push the bound states in both barriers 120, 126 higher in energy compared to the Fermi energy level of 0 volts, thus reducing their electron occupancy, and thereby reducing parasitic conduction through the barriers 120, 126 in the HEMT 110 in FIG. 6, compared to the parasitic conduction in the HEMT 10 in FIG. 1, which is shown as the conductive paths 34, 36 in FIG. 3. Furthermore, the potential “well” in the barriers 120, 126 in the HEMT 110 of the present invention are more pronounced at higher doping levels, and thus the ABC spacers 140, 142, 144, 146 enable higher doping of the barriers in the present invention without concomitantly increasing cross-barrier leakage or through-barrier parasitic conduction, as in the prior art. Thus, the present invention using ABC spacers enables HEMTs to be fabricated which operate with higher electron densities in the channel, higher current-handling capability, higher transconductance, and better linearity.

Moreover, the ABC spacers 140, 142, 144, 146 confer a reduction of tunneling current simply by virtue of offering taller barriers to the electrons, even without the additional advantage of preventing resonant tunneling described above. Thus, the ABC spacers 140, 142, 144, 146 reduce gate electron currents in all regimes of HEMT operation, whether in the ON-state with the gate voltage higher than a certain threshold voltage, or in the OFF-state where the gate voltage is sub-threshold.

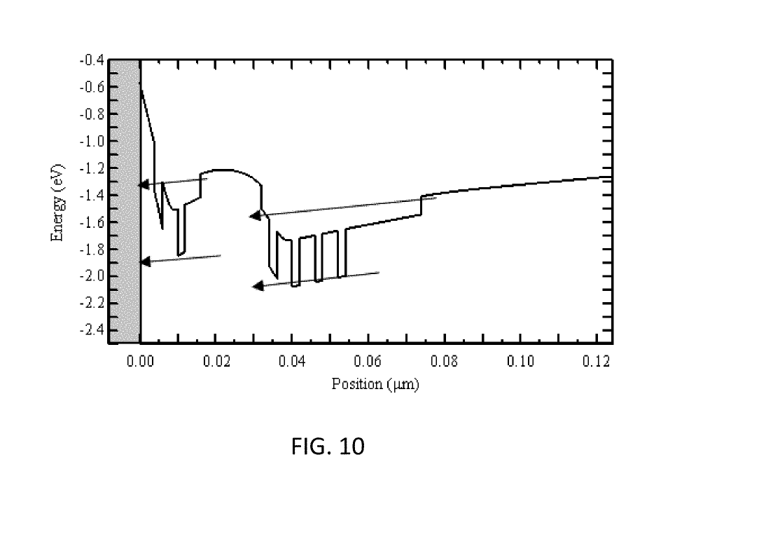

FIG. 10 illustrates electron-hole traversal of the barriers into the channel or the gate in the HEMT 110 of FIG. 6, due to either tunneling through the barriers or due to emission over the barriers. As shown in FIG. 10, the ABC spacers 140, 142, 144, 146, create taller barriers for these holes suppressing their transmission either by thermionic emission “over” the barriers, or by tunneling through the barriers. It is to be noted that valence band energy diagrams for electron-holes, such as shown in FIG. 10, are to be interpreted upside-down relative to the valence bands for electrons, and therefore the tallest barriers appear lowest on the diagram. Suppression of hole transport in the present invention, due to the use of ABC spacers, also results in suppression of the “kink” effect known in the prior art to cause a steep increase in drain current at large drain bias voltages.

In implementing the present invention, it might appear at first glance that composing the entire barrier 120, 126 out of the WBG material would bring the same advantages as narrow WBG ABC spacers, such as the ABC spacers 140, 142, 144, 146 in FIG. 6. However, it is generally difficult to grow thick layers of WBG material on a lower band-gap system because of point defects, dislocations formed from lattice mismatch, and other material quality issues that may increase leakage and/or reduce channel mobility. Moreover, often the barrier/channel material pair is chosen to confer to the HEMT a specific threshold gate voltage for conduction to begin, and it is necessary for circuit applications to retain this threshold voltage. On the other hand, a thin WBG ABC spacer within the barrier, as shown in FIG. 6, does not materially affect this threshold voltage.

As described above, the WBG ABC spacers within and/or adjacent to the respective barriers enable high donor doping levels in the barriers, and hence high electron charge density in the channel without concomitantly high electron density in the barriers. The WBG ABC spacers within and/or adjacent to the respective barriers push bound states of the electrons in the barriers upwards in energy, reducing their charge density and hence reducing parasitic conduction. The WBG ABC spacers within the respective barriers allow the engineering of quantum bound states in the barriers to be off-resonance with the channel bound states, thus reducing leakage of channel electrons through resonant tunneling from the channel through barrier into the remainder of the device in the ON-state, thus confining electron wavefunctions to the channel, and reducing their overlap with scattering donor centers in the barriers, thus increasing HEMT channel electron velocity.

The implementation of WBG ABC spacers within the respective barriers creates an energetically taller barrier for electrons which reduces thermionic emission as well as tunneling, and hence reduces sub-threshold OFF-state gate leakage. Furthermore, WBG ABC spacers within and/or adjacent to the respective barriers reduce tunneling and thermionic emission of electron-holes across the front and/or back barriers.

Therefore, HEMTs with highly doped HEMT barriers may be fabricated with a reduced electron charge density in the barriers to reduce parasitic conduction through the nominally insulating barriers of the HEMT, even in highly doped barriers. Such reductions in electron charge density are caused by having the bound-state energy Eᵢ be as far above the Fermi energy level E_{F} as possible. The present invention keeps electrons confined to the high-speed channel when the device is in the ON-state by reducing the resonant-tunneling mechanism which causes the ON-state leakage of channel electrons through the barriers and into the rest of the HEMT.

By keeping the electrons confined to the channel, the present invention has an increased speed of operation by reducing scattering by donor impurities in the barrier, thus increasing the electron mobility. This is achieved by having the bound states in the channel and barrier be off resonance.

The present invention also reduces the kink-effect caused by electron-holes accumulating near the source end of the channel due to tunneling or thermionic emissions across the barriers, and increasing the drain current, sometimes abruptly through an avalanche breakdown process.

The present invention improves linearity of the HEMT by enabling the utilization of heavily doped barriers, by improving channel electron mobility and reducing parasitic resistances and associated non-linearities, by reducing parasitic conduction across barrier(s), by reducing leakage through barrier(s).

The present invention also increases the effective Schottky barrier height, which enables enhancement-mode operation of the HEMT, as described in U.S. application Ser. No. 15/918,003, filed on Mar. 12, 2018, which is incorporated by reference in its entirety.

In an alternative embodiment, the present invention may apply ABC spacers in other types of FETs, not limited to HEMTs. For example, an ABC spacer may be disposed in a barrier of hole-channel (p-channel) FETs, in which the carriers of electrical current are holes rather than electrons. The ABC spacer would have similar band offset properties relative to the other materials in the barrier stack, except that the offsets would be in the valence band. The valence band-edge diagrams would be exact mirror images to the conduction band-edge diagrams presented above for n-channel FETs.

In another alternative embodiment, an ABC spacer may be disposed in a barrier of a FET that depletes a doped channel, i.e. a pre-existing bridge between the source and drain by applying a voltage opposite in polarity to the ionized impurities (dopants). Such FETs include Hetero-Junction FETs (HFETs), Junction Gate FETs (JFETs), and Metal-Semiconductor FETs (MESFETs).

In further alternative embodiments, ABC spacers may be disposed in a barrier of a FET in which the channel is a compositionally graded alloy such that the composition of one of the alloy constituents is varied in a piecewise linear or piecewise quadratic manner versus distance in the growth direction. The ABC spacer is composed of a wide-bandgap (WBG) material.

In further alternative embodiments, ABC spacers may be disposed in a barrier of an Enhancement-Mode FET or of a Depletion-Mode FET.

As described above, the present invention has been described in connection with a GaAs platform. That is, the HEMT 110 in FIG. 6 may have AlAs spacers, AlGaAs barriers, an Al(In)GaAs Schottky layer, and an (In)GaAs channel. However, the present invention does not depend on any special properties of (Al)(In)GaAs not present in other compound semiconductors or alloys. There is an uncountable infinity of combinations of elements that may be combined in varying proportions, and even though material growth constraints narrow this down considerably, advances in pseudomorphic and metamorphic growth technology are making it possible to grow more and more combinations on highly dissimilar substrates. Accordingly, in further alternative embodiments, channel/substrate combinations may include InGaAs/InP, InGaAlAs/InP, InAsP/InP, InGaAs/GaAs, or InAs/GaSb. Some alternative examples of barrier/spacer combinations include AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb. In still further alternative embodiments, combinations may be implemented in which the constituent elements are the same in the barrier as in the spacer, but the alloy compositions are different and are chosen such that the conduction band is raised in the spacer over the rest of the barrier.

The inventive device may be distinguished from prior art using a variety of experimental and analytical techniques. Gate and substrate leakage can be measured using current-voltage measurements, or through terminal noise measurements, or other techniques known in the art. The electron concentration and mobility in the channel and barrier may be deduced from Hall Effect measurements, or other methods as known in the art. Gate noise measurement techniques for HEMTs are well known in the art. Bound state energies and wave-functions in various regions of the device may be determined by simulation using Schrodinger-Poisson solvers and other techniques well known in the art. Linearity may be quantified by the “OIP3” figure-of-merit (third order output intercept point) among other metrics, and may be measured using two-tone techniques and others well known in the art.

The present invention may be embodied in other specific forms without departing from its spirit or essential characteristics. The described embodiments are to be considered in all respects only as illustrative and not restrictive. The scope of the invention, therefore, will be indicated by claims rather than by the foregoing description. All changes, which come within the meaning and range of equivalency of the claims, are to be embraced within their scope.

What is claimed is:

1. A field effect transistor (FET) comprising:
a substrate;
a back barrier disposed on the substrate;
a channel disposed on the back barrier; and
a front barrier disposed on the channel;
wherein at least one of the front barrier and the back barrier includes an anti-barrier-conduction (ABC) spacer.

2. The FET of claim 1, wherein the ABC spacer is grown by a fabrication method selected from a lattice matched growth, a pseudo-morphic growth and a metamorphic growth.

3. The FET of claim 1, wherein the ABC spacer is grown by a fabrication method selected from molecular beam epitaxy (MBE), metal-organic chemical vapor deposition (MOCVD), atomic layer deposition (ALD), thermal evaporation, and sputtering.

4. The FET of claim 1, wherein the ABC spacer is disposed adjacent to the channel.

5. The FET of claim 1, wherein the ABC spacer causes a conduction-band offset in the range of +0.1 eV to +10 eV relative to and above an energy level of at least one of the front barrier and the back barrier.

6. The FET of claim 1, wherein the ABC spacer is composed of a wide-bandgap (WBG) material.

7. The FET of claim 6, wherein a pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb.

8. The FET of claim 1 wherein the channel is alloy-compositionally graded in a piecewise linear manner.

9. The FET of claim 1 wherein the channel is alloy-compositionally graded in a piecewise quadratic manner.

10. The FET of claim 1, further comprising:
a source;
a drain; and
a gate.

11. The FET of claim 10, wherein the ABC spacer is disposed between the gate and the front barrier.

12. The FET of claim 10, wherein the ABC spacer reduces parasitic conduction on a path from the source to the drain through at least one of the front barrier and the back barrier.

13. The FET of claim 10, wherein the ABC spacer reduces ON-state leakage into the gate caused by resonant tunneling from the channel.

14. The FET of claim 10, wherein the ABC spacer reduces thermionic emission of at least one of electrons and electron-holes over one at least of the front and back barriers.

15. The FET of claim 10, wherein the ABC spacer reduces tunneling of at least one of electrons and electron-holes through at least one of the front and back barriers.

16. The FET of claim 10, wherein the ABC spacer improves the OIP3 figure of merit for linearity.

17. The FET of claim 10, wherein the ABC spacer reduces at least one of gate leakage, substrate leakage, and gate noise.

18. A high-electron mobility transistor (HEMT) comprising:
a substrate;
a back barrier disposed on the substrate;
a channel disposed on the back barrier;
a front barrier disposed on the channel;
a pulse-doping layer disposed in at least one of the front barrier and the back barrier; and
wherein at least one of the front barrier and the back barrier includes an anti-barrier-conduction (ABC) spacer.

19. The HEMT of claim 18, wherein the ABC spacer is composed of a wide-bandgap (WBG) material.

20. The HEMT of claim 19, wherein a pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb.

21. The HEMT of claim 18, further comprising:
a source; and
a drain;
wherein the ABC spacer reduces parasitic conduction on a path from the source to the drain through at least one of the front barrier and the back barrier.

22. A method comprising:
disposing a back barrier on a substrate;
disposing a channel on the back barrier;
disposing a front barrier on the channel; and
disposing an anti-barrier-conduction (ABC) spacer in relation to at least one of the front barrier and the back barrier.

23. The method of claim 22, wherein the ABC spacer is disposed adjacent to the channel.

24. The method of claim 22, wherein the ABC spacer is disposed within at least one of the front barrier and the back barrier.

25. The method of claim 22, further comprising:
disposing a source and a drain above the front barrier;
wherein the ABC spacer reduces parasitic conduction on a path from the source to the drain through at least one of the front barrier and the back barrier.

26. The method of claim 22, wherein the ABC spacer is composed of a wide-bandgap (WBG) material.

27. The method of claim 26, wherein a pair of one of the barrier materials/WBG material is selected from AlGaAs/AlAs, AlGaAs/GaP, AlGaAs/InGaP, InP/In(Ga)AlAs, In(Ga)AlAs/Al(Ga)AsSb, InP/Al(Ga)AsSb, InGaAlAs/InAlAs, AlGaAsSb/AlAsSb and AlGaSb/AlSb.
